(19) United States
(12) Patent Application Publication
(10) Pub. No.: US 2016/0172517 A1
(43) Pub. Date: Jun. 16, 2016

(54) REFLECTING FILMS WITH ROUNDED MICROSTRUCTURES FOR USE IN SOLAR MODULES

(71) Applicant: 3M INNOVATIVE PROPERTIES COMPANY, St. Paul, MN (US)

(72) Inventor: Jiaying Ma, Cottage Grove, MN (US)

(21) Appl. No.: 14/902,660

(22) PCT Filed: Jul. 1, 2014
(86) PCT No.: PCT/US2014/045029

§ 371 Date: Jan. 4, 2016

Related U.S. Application Data
(60) Provisional application No. 61/843,953, filed on Jul. 9, 2013.

(51) Int. Cl. H01L 31/056; G02B 19/00; G02B 5/08; H01L 31/0236

(52) U.S. Cl. CPC H01L 31/056; H01L 31/02366; G02B 19/0019; G02B 19/0042; G02B 5/0866

(57) ABSTRACT

Reflective microstructured films include a base layer, and an ordered arrangement of a plurality of microstructures projecting from the base layer. The microstructures have rounded peaks defined by an radius of curvature. Additionally, the micro-structures include a reflective layer. These reflective microstructured films can be used in solar modules.

### FIELD OF THE DISCLOSURE

The present disclosure relates to reflective microstructured films with rounded microstructured features, and their use in solar modules.

### BACKGROUND

Renewable energy is energy derived from natural resources that can be replenished, such as sunlight, wind, rain, tides, and geothermal heat. The demand for renewable energy has grown substantially with advances in technology and increases in global population. Although fossil fuels provide for the vast majority of energy consumption today, these fuels are non-renewable. The global dependence on these fossil fuels has not only raised concerns about their depletion but also environmental concerns associated with emissions that result from burning these fuels. As a result of these concerns, countries worldwide have been establishing initiatives to develop both large-scale and small-scale renewable energy resources. One of the promising energy resources today is sunlight. Globally, millions of households currently obtain power from solar photovoltaic systems. The rising demand for solar power has been accompanied by a rising demand for devices and materials capable of fulfilling the requirements for these applications.

Harnessing sunlight may be accomplished by the use of photovoltaic (PV) cells (solar cells), which are used for photoelectric conversion, e.g., silicon photovoltaic cells. PV cells are relatively small in size and typically combined into a physically integrated PV module (solar module) having a correspondingly greater power output. PV modules are generally formed from 2 or more “strings” of PV cells, with each string consisting of a plurality of cells arranged in a row and electrically connected in series using tinned flat copper wires (also known as electrical connectors, tabbing ribbons or bus wires). These electrical connectors are typically adhered to the PV cells by a soldering process.

PV modules typically comprise a PV cell surrounded by an encapsulant, such as generally described in U.S. Patent Publication No. 2008/0078445 (Patel et al). In some embodiments, the PV module includes encapsulant on both sides of the PV cell. Two panels of glass (or other suitable polymeric material) are positioned adjacent and bonded to the front-side and backside of the encapsulant. The two panels are transparent to solar radiation and are typically referred to as front-side layer and backside layer, or backsheet. The front-side layer and the backsheet may be made of the same or a different material. The encapsulant is a light-transparent polymer material that encapsulates the PV cells and also is bonded to the front-side layer and backsheet so as to physically seal off the cells. This laminated construction provides mechanical support for the cells and also protects them against damage due to environmental factors such as wind, snow, and ice. The PV module is typically fit into a metal frame, with a sealant covering the edges of the module engaged by the metal frame. The metal frame protects the edges of the module, provides additional mechanical strength, and facilitates combining it with other modules so as to form a larger array or solar panel that can be mounted to a suitable support that holds the modules at the proper angle to maximize reception of solar radiation.

The art of making photovoltaic cells and combining them to make laminated modules is exemplified by the following U.S. Pat. No. 4,751,191 (Gonsiorawski et al.); U.S. Pat. No. 5,074,920 (Gonsiorawski et al.), U.S. Pat. No. 5,118,362 (St. Angelo et al.); U.S. Pat. No. 5,178,685 (Borenstein et al.); U.S. Pat. No. 5,320,684 (Amick et al); and U.S. Pat. No. 5,478,402 (Hanoka).

### SUMMARY

Described herein are reflective microstructured films with microstructured features that have round peaks, solar modules prepared from these reflective microstructured films, and methods of preparing solar modules.

In some embodiments, the reflective film comprises a base layer, and an ordered arrangement of a plurality of microstructures projecting from the base layer. The microstructures have rounded peaks that are defined by a radius of curvature. Additionally, the microstructures comprise a reflective layer.

Also described herein are solar modules. In some embodiments, the solar modules comprise a plurality of solar cells, and a reflective film, where the reflective film has been described above.

Additionally, methods for preparing solar modules are described. The methods comprise providing a reflective film, providing a plurality of solar cells arranged on a support substrate and connected by tabbing ribbons, attaching the reflecting film to the solar cells and adjacent areas, and attaching a transparent cover layer over the reflecting film. The reflective films have been described above.

### BRIEF DESCRIPTION OF THE DRAWINGS

The present application may be more completely understood in consideration of the following detailed description of various embodiments of the disclosure in connection with the accompanying drawings.

FIG. 1 shows a cross sectional of a structured reflective film of an embodiment of this disclosure.

FIG. 2 shows a cross sectional view of the structured reflective film of FIG. 1 with a circle superimposed on one structure to illustrate the radius of curvature of the structure.

FIG. 3 shows an expanded view of the structure of FIG. 2 with a superimposed circle to illustrate the radius of curvature of the structure.

In the following description of the illustrated embodiments, reference is made to the accompanying drawings, in which is shown by way of illustration, various embodiments in which the disclosure may be practiced. It is to be understood that the embodiments may be utilized and structural changes may be made without departing from the scope of the present disclosure. The figures are not necessarily to scale. Like numbers used in the figures refer to like components. However, it will be understood that the use of a number to refer to a component in a given figure is not intended to limit the component in another figure labeled with the same number.

### DETAILED DESCRIPTION

Solar modules generally are prepared as laminated arrays of photovoltaic solar cells. The array is generally between a support layer that is generally clear, such as glass or a transparent polymeric material, and a cover layer that is also generally transparent and may be the same material as the support layer or it may be different. Because the solar cells themselves are fairly small and cover only part of the total surface area of the module, a variety of techniques have been developed to direct more sunlight onto the solar cell and thus increase the efficiency of the module. In one technique, described in U.S. Pat. No. 4,235,643 (Amick) an optical medium having a plurality of light-reflective facets is disposed between adjacent cells. The light-reflective facets are angularly disposed so as to define a plurality of grooves with the angle at the vertex formed by two mutually converging facets being between 110° to 130°, preferably about 120°. The result of these facets is that light impinging on the facets will be reflected back into the transparent front cover member at an angle greater than the critical angle, and is then reflected again internally from the front surface of the cover member so as to impinge on the solar cells. In U.S. Pat. No. 5,994,641 (Kardauskas), a flexible reflector means is used as the optical medium having a plurality of grooves. The flexible reflector means is an optically reflective sheet material with a coating of reflective metal such as silver or aluminum. The facets of the reflective sheet material have sharp peaks.

In this disclosure, reflective films (sometimes referred as light directing mediums) useful in solar modules are described. Such reflective films have a generally planar back surface and a structured front surface. The structured front surface comprises an array of microstructures having rounded peaks. These rounded peak reflective films have a variety of advantages over the sharp peak reflective films that have been previously described.

One advantage of the rounded peak reflective films over the sharp peak reflective films, relates to the coating of the peaks with a layer of reflective metal. Typically, the reflective layers of the reflective films are metal coating layers. The metal coating is typically done by metal vaporization techniques. Depositing a layer of metal on rounded peaks is easier than depositing on sharp peaks. Even more importantly than the ease of depositing however, is the fact that when the peaks are sharp, that is to say that the peaks come to a point, it is very difficult to adequately cover the sharp peak with a layer of metal. This can, and often does, result in a “pinhole” at the peak of the facet where little or no metal is present. These pinholes not only do not reflect light, but also because the polymeric material is inadequately covered with metal, sunlight is permitted to pass through and impinge upon the polymeric material of the facet. Over time the sunlight can cause the polymeric material of the facet to degrade and compromise the structural integrity of the facet and thus of the reflective film in general.

Rounded peak films on the other hand do not have the sharp peaks and thus are easier to coat. This is because the shape of the peak changes more gradually rather than coming to a sharp point. Because the peaks are rounded and do not come to a sharp peak, it is more like coating a flat film and it is consequently easier to provide a uniform metal coating. More importantly, the risk of pinholes is reduced or eliminated.

Another advantage of the rounded peak films over the sharp peak reflective films, relates to handling of these films. Once the facets are incorporated into the film surface, a variety of handling steps are involved. For example, there are a variety of handling steps involved in coating the facets with the reflective metal layer. In many instances, the films are coated with metal in a different location from where the facets are incorporated into the film surface. Often the films are rolled up and transported, unrolled, the metal coating is applied, and then the films are again rolled up. The metal coated films often are then transported to yet another location to turn the sheet of film into useful articles of the proper size and shape. This process is typically referred to as “converting” in the film art. When the films are converted, they are again unrolled, the film is slit, or cut to the desired size and shape and then may be packaged for shipment to another location for incorporation to a solar module. Many variations on this sequence of steps are possible and additional steps may also be used such as laminating an adhesive layer to the film article for adherence to the solar module. It may be possible, for example, for the structuring (incorporation of facets into the film), metal coating, and converting to be done as a continuous process in a single location, but even in such an integrated process, there are still handling steps, not to mention the steps of shipping the film article to the solar module assembly location, and the assembly of the solar module itself. With sharp peak films, each of these handling steps provides the potential for the sharp peaks to become damaged. This is especially true with processes where the film is rolled upon itself and the sharp peaks contact the back side of the film. Damage to the sharp peaks can not only affect the aesthetic appearance of the film, it can diminish the ability of the film to reflect sunlight. This damage can occur to the peaks of the film itself, it can occur to the peaks after they are coated with a layer of reflective metal, or a combination of damage to the film and metal coated film is possible.

Rounded peak films on the other hand are easier to handle, and there are no sharp peaks vulnerable to damage during processing, shipping, converting, and other handling steps.

Unless otherwise indicated, all numbers expressing feature sizes, amounts, and physical properties used in the specification and claims are to be understood as being modified in all instances by the term “about.” Accordingly, unless indicated to the contrary, the numerical parameters set forth in the foregoing specification and attached claims are approximations that can vary depending upon the desired properties sought to be obtained by those skilled in the art utilizing the teachings disclosed herein. The recitation of numerical ranges by endpoints includes all numbers subsumed within that range (e.g. 1 to 5 includes 1, 1.5, 2, 2.75, 3, 3.80, 4, and 5) and any range within that range.

As used in this specification and the appended claims, the singular forms “a”, “an”, and “the” encompass embodiments having plural referents, unless the content clearly dictates otherwise. For example, reference to “a layer” encompasses embodiments having one, two or more layers. As used in this specification and the appended claims, the term “or” is generally employed in its sense including “and/or” unless the content clearly dictates otherwise.

As used herein, the term “ordered arrangement” when used to describe microstructural features, especially a plurality of microstructures, means an imparted pattern different from natural surface roughness or other natural features, where the arrangement can be continuous or discontinuous, can be a repeating pattern, a non-repeating pattern, a random pattern, etc.

As used herein, the term “microstructure” means the configuration of features wherein at least 2 dimensions of the features are microscopic. The topical and/or cross-sectional view of the features must be microscopic.

As used herein, the term “microscopic” refers to features of small enough dimension so as to require an optic aid to the naked eye when viewed from any plane of view to determine its shape. One criterion is found in Modem Optic Engineering by W. J. Smith, McGraw-Hill, 1966, pages 104-105 whereby visual acuity, “. . . is defined and measured in terms of the angular size of the smallest character that can be recognized.” Normal visual acuity is considered to be when the smallest recognizable letter subtends an angular height of 5 minutes of arc on the retina. At a typical working distance of 250 mm (10 inches), this yields a lateral dimension of 0.36 mm (0.0145 inch) for this object.

The term “(meth)acrylate” refers to monomeric acrylic or methacrylic esters of alcohols. Acrylate and methacrylate monomers or oligomers are referred to collectively herein as “(meth)acrylates”. Polymers described as “(meth)acrylate-based” are polymers or copolymers prepared primarily (greater than 50% by weight) from (meth)acrylate monomers and may include additional ethylenically unsaturated monomers.

Unless otherwise indicated, “optically transparent” refers to an article, film or adhesive composition that has a high light transmittance over at least a portion of the visible light spectrum (about 400 to about 700 nm).

The term “adjacent” as used herein when referring to two layers means that the two layers are in proximity with one another with no intervening open space between them. They may be in direct contact with one another (e.g. laminated together) or there may be intervening layers.

As used herein the term “critical angle” refers to the largest value which the angle of incidence may have for a ray of light passing from a more dense optical medium to a less dense optical medium. If the angle of incidence exceeds the critical angle, the ray of light will not enter the less dense medium but will be totally internally reflected back into the denser medium.

Disclosed herein are reflective films suitable for use in preparing solar modules. These films comprise a base layer, and an ordered arrangement of a plurality of microstructures projecting from the base layer, the microstructures having rounded peaks, and comprising a reflective layer.

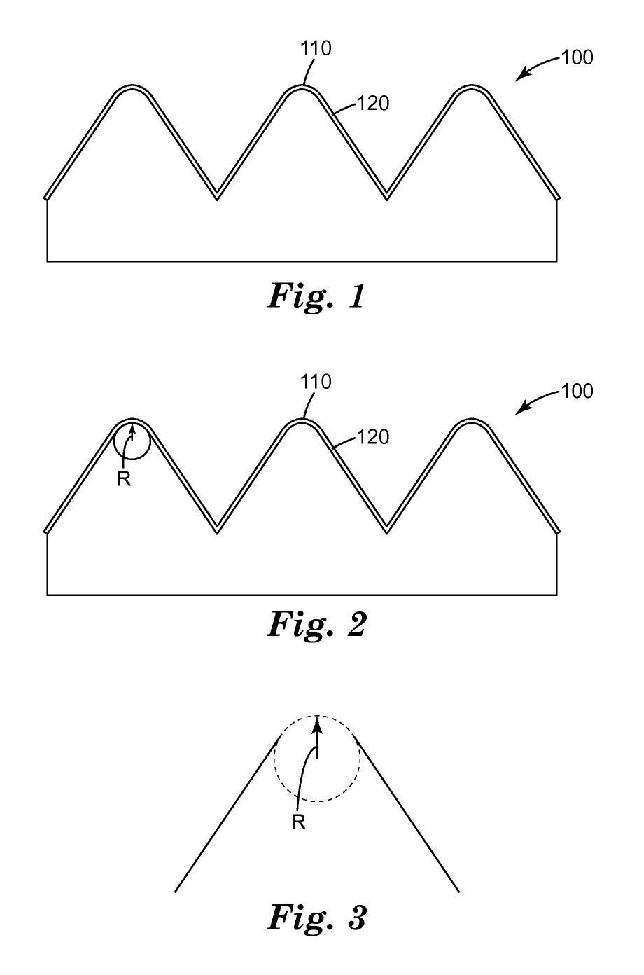

FIG. 1 shows a cross sectional view of a microstructured reflective film of the present disclosure. In FIG. 1, reflective film 100 contains microstructured features 110, which are rounded peaks, and contain reflective layer 120. Typically, reflective layer 120 is a reflective metal coating layer comprising silver or aluminum, more typically aluminum for cost reasons. The microstructures protrude 5 micrometers to 500 micrometers from the base layer.

The rounded microstructures can be described as having a radius of curvature. This radius of curvature is shown in FIG. 2 which is a cross sectional view of film 100 as shown in FIG. 1, with a circle superimposed upon one of the rounded microstructures. The superimposed circle has radius R, and this radius R is defined as the radius of curvature. Typically, the radius of curvature is 0.1 to 5.0 micrometers, more typically 0.2 to 5.0 micrometers.

FIG. 3 shows an expanded view of one of the microstructures of the film of FIG. 2, showing the superimposed circle having radius R, this radius R defining the radius of curvature.

The base layer material comprises a polymeric material. A wide range of polymeric materials are suitable for preparing the base layer. Examples of suitable polymeric materials include cellulose acetate butyrate; cellulose acetate propionate; cellulose triacetate; poly(meth)acrylates such as polymethyl methacrylate; polyesters such as polyethylene terephthalate, and polyethylene naphthalate; copolymers or blends based on naphthalene dicarboxylic acids; polyether sulfones; polyurethanes; polycarbonates; polyvinyl chloride; syndiotactic polystyrene; cyclic olefin copolymers; silicone-based materials; and polyolefins including polyethylene and polypropylene; and blends thereof. Particularly suitable polymeric materials for the base layer are polyolefins and polyesters.

Typically, the microstructures also comprise a polymeric material. In some embodiments, the polymeric material of the microstructures is the same composition as the base layer. In other embodiments, the polymeric material of the microstructures is different from that of the base layer. In some embodiments, the base material layer is a polyester and the microstructure material is a poly(meth)acrylate.

In some embodiments, the microstructured film is prepared by imparting microstructures onto a film. In these embodiments, the base layer and the microstructures comprise the same polymeric composition. In other embodiments, the layer of microstructures is prepared separately and laminated to the base layer. This lamination can be done using heat, a combination of heat and pressure, or through the use of an adhesive. In still other embodiments, the microstructures are formed on the base layer.

The microstructured film or a layer of microstructures may be prepared by embossing. In this process, a flat film with an embossable surface is contacted to a structured tool with the application of pressure and/or heat to form an embossed surface. The entire flat film may comprise an embossable material, or the flat film may only have an embossable surface. The embossable surface may comprise a layer of a material that is different from the material of the flat film, that is to say that the flat film may have a coating of embossable material at its surface. The embossed surface is a structured surface. The structure on the embossed surface is the inverse of structure on the tool surface, that is to say a protrusion on the tool surface will form a depression on the embossed surface, and a depression on the tool surface will form a protrusion on the embossed surface. The microstructural features may assume a variety of shapes as long as the peaks of the structures are rounded. An example of methods of forming rounded microstructural features are described, for example, in U.S. Pat. No. 6,280,063 (Fong et al.).

Typically, the microstructured tool is a molding tool. Structured molding tools can be in the form of a planar stamping press, a flexible or inflexible belt, or a roller. Furthermore, molding tools are generally considered to be tools from which the microstructured pattern is generated in the surface by embossing, coating, casting, or platen pressing and do not become part of the finished article. An example of a molding process that can be used to form the microstructural features is described in PCT Publication No. WO 2012/082391.

A broad range of methods are known to those skilled in this art for generating microstructured molding tools. Examples of these methods include but are not limited to photolithography, etching, discharge machining, ion milling, micromachining, and electroforming. Microstructured molding tools can also be prepared by replicating various microstructured surfaces, including irregular shapes and patterns, with a moldable material such as those selected from the group consisting of crosslinkable liquid silicone rubber, radiation curable urethanes, etc. or replicating various microstructures by electroforming to generate a negative or positive replica intermediate or final embossing tool mold. Also, microstructured molds having random and irregular shapes and patterns can be generated by chemical etching, sandblasting, shot peening or sinking discrete structured particles in a moldable material. Additionally any of the microstructured molding tools can be altered or modified according to the procedure taught in U.S. Pat. No. 5,122,902 (Benson). The tools may be prepared from a wide range of materials including metals such as nickel, copper, steel, or metal alloys, or polymeric materials.

As mentioned above, the base layer and the microstructured layer may comprise a single construction and are thus made from the same material. There are also several methods for generating a microstructured layer without the microstructured layer being part of the base layer. For example, a curable or molten polymeric material could be cast against the microstructured molding tool and allowed to cure or cool to form a microstructured layer in the mold. This layer, in the mold, could then be adhered to a polymeric film, either through heat and/or pressure or through the use of an adhesive such as a pressure sensitive adhesive or curable adhesive. The molding tool could then be removed to generate the construction with a base layer and a microstructured layer. In a variation of this process, the molten or curable polymeric material in the microstructured molding tool could be contacted to a film and then cured or cooled. In the process of curing or cooling the polymeric material in the molding tool can adhere to the film. Upon removal of the molding tool, the construction is formed comprising a base layer (the film) and a microstructured layer. In some embodiments, the microstructured layer is prepared from a radiation curable (meth)acrylate material, and the molded (meth)acrylate material is cured by exposure to actinic radiation.

The layer of microstructures has a reflective layer on its surface. Any suitable reflective layer may be used, such as, for example a reflective metallic coating. When reflective metal coatings are used, the coating is typically silver, aluminum, or a combination thereof. Aluminum is more typical, but any suitable metal coating can be used. Generally the metallic layer is coated by vapor deposition, using well understood procedures. The metallic coating is very thin, generally on the order of 300-1000 Angstroms thick, more typically 300-500 Angstroms.

Also disclosed herein are solar modules. These solar modules comprise a plurality of solar cells, and a reflective film comprising a plurality of microstructures projecting from a base layer, the microstructures having rounded peaks, and comprising a reflective layer. The reflective films have been described above. The array of solar cells is generally between a support layer that is generally clear, such as glass or a transparent polymeric material and a cover layer that is also generally transparent and may be the same material as the support layer or it may be different.

Also disclosed herein are methods of preparing solar modules. These methods include providing a reflective film, the reflective film comprising a plurality of microstructures projecting from a base layer, the microstructures having rounded peaks, and comprising a reflective layer, providing a plurality of solar cells arranged on a support substrate and connected by tabbing ribbons, attaching the reflecting film to the solar cells and adjacent areas, and attaching a transparent cover layer over the reflecting film. The reflective film is described above.

In some embodiments, the reflective film is placed adjacent to the tabbing ribbons. The tabbing ribbons (electrical connectors) create shaded areas that are inactive, that is to say that light impinging onto these areas is not used for photovoltaic conversion. Placement of reflective film adjacent to these tabbing ribbons can thus increase the energy generated by the solar module, as is discussed in US Patent Attorney Docket No. 69734US002 filed Mar. 27, 2013.

What is claimed is:

1. A reflecting film comprising:
a base layer; and
an ordered arrangement of a plurality of microstructures projecting from the base layer,
the microstructures having rounded peaks, and comprising a reflective layer.

2. The reflecting film of claim 1, wherein the microstructures protrude 5 micrometers to 500 micrometers from the base layer.

3. The reflecting film of claim 1, wherein the rounded peaks of the microstructures have a radius of curvature of from 0.2 micrometers to 5 micrometers.

4. The reflecting film of claim 1, wherein the base layer comprises a polymeric layer.

5. The reflecting film of claim 1, wherein the microstructures comprise a polymeric material.

6. The reflecting film of claim 5, wherein the microstructures comprise the same polymeric material as the base layer.

7. The reflecting film of claim 5, wherein the microstructures comprise a different polymeric from the base layer.

8. The reflecting film of claim 1, wherein the reflective layer comprises a metallic coating.

9. The reflecting film of claim 8, wherein the metallic coating comprises aluminum, silver, or a combination thereof.

10. A solar module comprising:
a plurality of solar cells; and
a reflective film, the reflective film comprising:
a base layer; and
an ordered arrangement of a plurality of microstructures projecting from the base layer, the microstructures having rounded peaks, and comprising a reflective layer.

11. The solar module of claim 10, wherein the microstructures protrude 5 micrometers to 500 micrometers from the base layer.

12. The solar module of claim 10, wherein the rounded peaks of the microstructures have a radius of curvature of from 0.2 micrometers to 5 micrometers.

13. The solar module of claim 10, wherein the reflective layer comprises a metallic coating.

14. The solar module of claim 13, wherein the metallic coating comprises aluminum, silver, or a combination thereof.

15. The solar module of claim 10, wherein the reflective film is located adjacent to the solar cells and/or adjacent to tabbing ribbons connecting the solar cells.

16. A method of preparing a solar module comprising:
providing a reflective film, the reflective film comprising:
a base layer; and
an ordered arrangement of a plurality of microstructures projecting from the base layer, the microstructures having rounded peaks, and comprising a reflective layer;
providing a plurality of solar cells arranged on a support substrate and connected by tabbing ribbons;
attaching the reflecting film to the solar cells and/or adjacent areas; and
attaching a transparent cover layer over the reflecting film.

17. The method of claim 16, wherein the microstructures protrude 5 micrometers to 500 micrometers from the base layer.

18. The method of claim 16, wherein the rounded peaks of the microstructures have a radius of curvature of from 0.2 micrometers to 5 micrometers.

19. The method of claim 16, wherein the reflective layer comprises a metallic coating.

20. The method of claim 19, wherein the metallic coating comprises aluminum, silver, or a combination thereof.

21. The method of claim 16, wherein the reflecting film is attached adjacent to at least a portion of the tabbing ribbons.
